(19) United States
(12) Patent Application Publication
(10) Pub. No.: US 2011/0309067 A1
(43) Pub. Date: Dec. 22, 2011

(54) Heater Device and Method of Making Same

(75) Inventor: Matthew J. Krussow, Overland Park, KS (US)

(73) Assignee: Heatron, Inc., Leavenworth, KS (US)

(21) Appl. No.: 13/162,078

(22) Filed: Jun. 16, 2011

Related U.S. Application Data
(60) Provisional application No. 61/356,066, filed on Jun. 18, 2010.

(51) Int. Cl. H05B 3/02; B05D 1/36; B05D 5/12; H05K 1/00; H05K 1/09

(52) U.S. Cl. 219/546; 174/258; 174/257; 427/58

(57) ABSTRACT

Electrically conductive traces, circuits, and devices such as heaters using such are described. Also described are various methods of forming the electrically conductive traces and circuits.

### FIELD OF THE INVENTION

The present invention relates to electrically resistive heating traces and circuits, a resistive heating device using such traces and circuits, and methods of forming the traces, circuits and heaters.

### BACKGROUND OF THE INVENTION

A wide array of electrically resistive heaters are known in the art. Accordingly, numerous techniques for forming such have also been developed. A significant component of the complexity and cost in producing small yet reliable electrically resistive heating circuits stems from curing and post-formation operations that are performed after initial circuit formation or deposition on a substrate. In processes involving polymer thick films, typically, one or more curing, heating, or other operations must be performed to transform the material or collection of materials constituting the circuit into a useable heating element that can receive electrical current and generate heat as a result of current flow through the element. In other processes such as those utilizing etched foil, hazardous chemicals or those necessitating costly recovery operations are employed.

Accordingly, a need exists for a relatively simple, inexpensive, and reliable strategy for forming electrically resistive circuits that upon deposition on a substrate can be immediately or nearly so, used as resistive heating elements.

### SUMMARY OF THE INVENTION

The difficulties and drawbacks associated with previously known systems are addressed by the present invention directed to electrically resistive traces and circuits, heating devices, and methods of forming such.

In one aspect, the present invention provides an electrically conductive trace comprising a polymeric substrate layer defining an underside face and an oppositely directed receiving face. The trace also comprises a thermoplastic adhesive layer disposed on the receiving face of the polymeric substrate layer. And, the trace comprises an electrically conductive layer disposed on the thermoplastic adhesive layer. The trace further comprises a thermoplastic release layer disposed on the electrically conductive layer.

In another aspect, the present invention provides a heating device having at least one electrically resistive heating circuit disposed on a substrate. The circuit includes an electrically conductive trace, the trace comprising a thermoplastic adhesive layer disposed on the substrate. The trace also comprises an electrically conductive layer disposed on the thermoplastic adhesive layer. And, the trace further comprises a thermoplastic release layer disposed on the electrically conductive layer.

In yet another aspect, the invention provides a method of forming an electrically conductive trace on a substrate. The method comprises providing a substrate defining a receiving face. The method also comprises providing a thermal transfer printer and a thermal transfer ribbon. The ribbon includes (i) an outermost thermoplastic adhesive layer, (ii) an electrically conductive material, (iii) a thermoplastic release layer, and (iv) a carrier film. The printer includes provisions for selectively moving and advancing the ribbon. The method additionally comprises printing (i) the thermoplastic adhesive layer, (ii) the electrically conductive material, and (iii) the thermoplastic adhesive layer on the receiving face of the substrate to form the trace.

As will be realized, the invention is capable of other and different embodiments and its several details are capable of modifications in various respects, all without departing from the invention. Accordingly, the drawings and description are to be regarded as illustrative and not restrictive.

### BRIEF DESCRIPTION OF THE DRAWINGS

FIG. 1 is a schematic illustration of a preferred embodiment process for forming a preferred embodiment resistive heating trace in accordance with the present invention.

FIG. 2 is a cross sectional schematic view of another preferred embodiment resistive heating trace in accordance with the invention.

FIG. 3 is a cross sectional schematic view of yet another preferred embodiment resistive heating trace in accordance with the invention.

FIG. 4 is a cross sectional schematic view of still another preferred embodiment resistive heating trace in accordance with the present invention.

FIG. 5 is a cross sectional schematic view of another preferred embodiment resistive heating trace in accordance with the invention.

FIG. 6 illustrates a preferred embodiment heater formed in accordance with the present invention.

FIG. 7 illustrates a cross sectional schematic view of a preferred embodiment thermal print ribbon prior to printing used in the present invention.

FIG. 8 illustrates a cross sectional schematic view of a preferred embodiment substrate for receiving a trace in accordance with the invention.

FIG. 9 illustrates a cross sectional schematic view of an alternate preferred embodiment substrate for receiving a trace in accordance with the invention.

FIG. 10 illustrates a cross sectional schematic view of a preferred embodiment trace disposed on a preferred embodiment substrate in accordance with the invention.

FIG. 11 illustrates a cross sectional schematic view of another preferred embodiment trace disposed on a preferred embodiment substrate in accordance with the invention.

FIG. 12 illustrates a cross sectional schematic view of another preferred embodiment thermal print ribbon prior to printing used in the present invention.

FIG. 13 illustrates a cross sectional schematic view of yet another preferred embodiment trace disposed on a preferred embodiment substrate in which a dielectric cover layer is disposed on the trace, in accordance with the invention.

### DETAILED DESCRIPTION OF THE EMBODIMENTS

The present invention relates to electrically conductive traces and circuits that are particularly adapted for use in resistive heating patterns used in heating devices and heating systems. The invention provides various methods for rapidly, conveniently, and inexpensively producing the traces and circuits. After formation of the traces and circuits, they can be immediately or substantially so, used to generate heat.

Specifically, the present invention relates to forming electrically resistive heating traces and circuits by use of thermal transfer printers using a thermal transfer ribbon. After designing a desired resistive heater circuit, i.e. designing the circuit configuration, pattern, size, and trace lengths, widths and thicknesses; the design information is forwarded to a thermal printer. The thermal printer then prints or otherwise forms the desired heating circuit onto a substrate using a thermal transfer ribbon. The ribbon comprises a particular electrically conductive composition and layered arrangement of one or more polymeric thermoplastic materials. Upon printing, the electrically conductive composition and associated polymeric layers are transferred directly to a wide array of substrates. The layered array formed after printing does not require any post treatment and is usable immediately or substantially so, after printing.

### Electrically Conductive Traces, Circuits, and Their Formation

The preferred embodiment electrically conductive traces and circuits are preferably in the form of a layered configuration that includes (without regard to order) (i) at least one layer of one or more thermoplastic materials, (ii) a layer including an electrically conductive material, (iii) a base layer, and (iv) an optional adhesive layer. More preferably, the layered configuration includes a layer of a first thermoplastic material, a layer of an electrically conductive material, a layer of a second thermoplastic material, a base film layer, and a layer of a pressure sensitive adhesive. Most preferably, the electrically conductive material is disposed between the layers of thermoplastic materials.

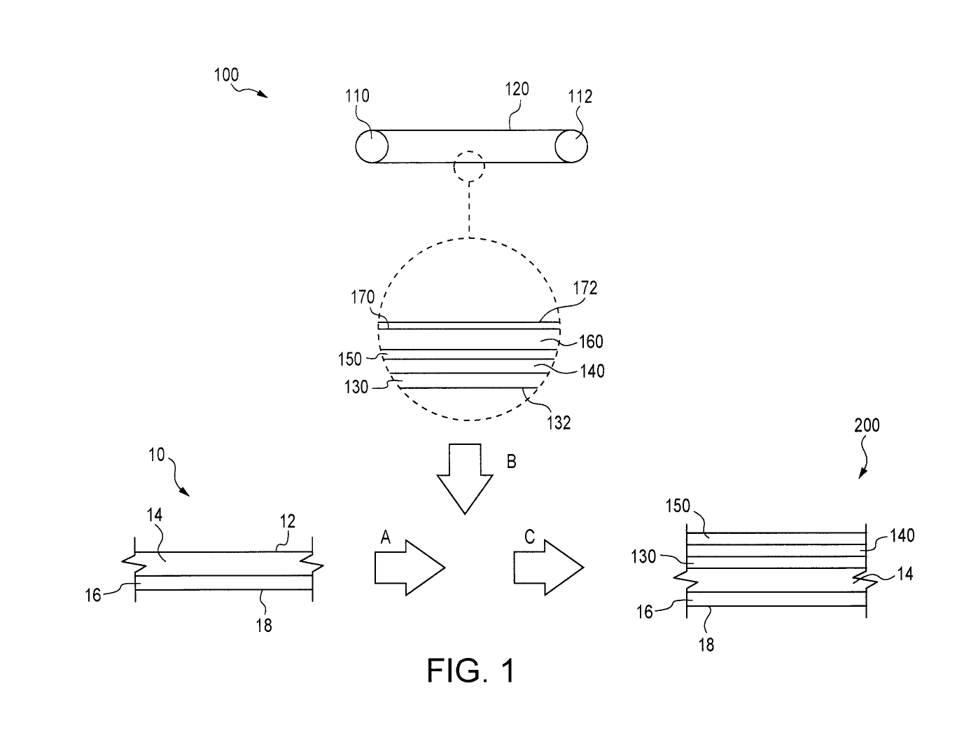

FIG. 1 schematically depicts a preferred embodiment process for forming a preferred embodiment trace 200 in accordance with the invention. FIG. 1 also illustrates preferred schematic cross sections of components at various phases within the process. Referring to FIG. 1, a substrate 10 for receiving an electrically conductive layer is provided. The substrate 10 generally comprises a base layer 14 of a polymeric material such as a polyester for example polyethylene terephthalate (PET) or a treated polyimide. However, it will be appreciated that the present invention is not limited to the use of these particular materials. Examples of other materials suitable for the substrate include other polyesters and variants of these with other materials. The substrate layer may be heat stabilized such as for example, by methods known in the art. The substrate 10 and specifically the base layer 14, defines a receiving face 12 for receiving one or more layers that include an electrically conductive layer, as described in greater detail herein. The substrate 10 may additionally comprise an optional adhesive layer 16 disposed along an underside face of the substrate, oppositely directed from the receiving face 12. Although nearly any type of adhesive may be used for layer 16, generally, a pressure sensitive adhesive with an associated liner or release layer (not shown) may be used to cover an exposed adhesive face 18. The base layer 14 can be provided in a range of different thicknesses. The thickness of the optional adhesive layer 16 generally depends upon the end use requirements of the heating circuit and/or heater.

Continuing to refer to FIG. 1, a system or assembly 100 for transferring one or more layers including an electrically conductive layer onto the substrate 10 is also provided. Although a wide array of systems and components can be used for the assembly 100, preferably the system is in the form of a thermal printing system using a thermal print ribbon 120 that carries the material layers targeted for application to the substrate 10. Generally, a thermal printing system comprises a thermal print ribbon 120 that is selectively advanced and/or positioned by use of one or more carriage rollers 110 and/or by one or more drive rollers 112. The thermal print ribbon 120 is preferably a multilayer laminate as schematically depicted in FIG. 1. As will be appreciated by those skilled in the art, thermal printers also comprise one or more printheads, an operator interface, provisions for moving the ribbon and/or the printhead, and electronics and processing provisions for controlling and operating the printing system. Additional details pertaining to thermal printers are provided in greater detail herein.

FIG. 1 further illustrates a representative preferred arrangement of layers for the thermal print ribbon 120. An outermost thermoplastic adhesive layer 130 defining an outer face 132 is provided. This layer can include nearly any polymeric thermoplastic material suitable for forming the traces and having a glass transition temperature (Tg) of approximately from about 60° C. to about 120° C., more preferably from about 80° C. to about 90° C., and most preferably about 85° C. The selection and use of materials exhibiting these particular glass transition temperatures promotes adherence of the electrically conductive material described below, to the substrate 10. Generally, the thickness of the adhesive layer 130 is from about 0.1 micron to about 1 micron, with about 0.5 micron being preferred.

The thermal print ribbon 120 also comprises a layer 140 of an electrically conductive material. Nearly any suitable electrically conductive material can be used, such as but not limited to aluminum, silver, gold, and combinations thereof. It is also contemplated that mixtures or agglomerates of polymeric matrix materials and electrically conductive materials in particulate or flake form could be used in layer 140. The electrically conductive layer 140 can be formed and incorporated into the print ribbon 120 in a wide array of techniques. Vapor deposition is an example of one such technique and is preferred for many applications. The electrically conductive layer 140 can be formed in a range of thicknesses such as from about 50 angstroms (0.005 microns) to about 4500 angstroms (0.45 microns), with about 2500 angstroms (0.25 microns) being preferred.

The thermal print ribbon 120 additionally comprises a layer 150 which includes a thermoplastic release layer. This layer can be formed from nearly any thermoplastic polymer suitable for forming the traces and having a glass transition temperature (Tg) of from about 60° C. to about 120° C., more preferably from about 80° C. to about 90° C., and most preferably about 85° C. The use of thermoplastic polymers exhibiting these glass transition temperatures enables release of the electrically conductive material from its carrier, i.e. the thermal print ribbon 120, onto the substrate 10. The thickness of the thermoplastic release layer 150 is not particularly critical, however is generally less than 1 micron, and typically less than 0.1 micron in thickness. The minimum thickness is typically about 0.01 micron. The thickness of the release layer should be such that subsequent printing operations are not detrimentally impacted. That is, if the release layer is too thick, greater amounts of energy would be required in order to sufficiently heat the release layer and associated adhesive layers to their glass transition temperatures as the print ribbon moves across the printhead. This would result in reducing the speed of printing and potentially, preclude transfer of the layers from the ribbon.

The thermal print ribbon 120 also comprises a carrier film 160, which is preferably a polymeric carrier film. Although a wide array of film materials may be used for layer 160 of the ribbon 120, preferably this layer 160 includes or is generally formed from polyethylene terephthalate (PET). The layer 160 can be provided having a range of thicknesses such as for example from about 3 microns to about 6 microns, with about 4.5 microns being preferred.

The thermal print ribbon 120 also preferably comprises a lubrication layer 170 defining an exposed face 172 that contacts the rollers 110, 112 and a printhead (not shown). A wide range of materials can be utilized for the lubrication layer 170. Silicone is generally preferred with cross-linked silicone being most preferred. The provision of a lubrication layer 170 in the thermal print ribbon 120 enables smooth and low friction passage of film over the printhead used in the system 100.

With continued reference to FIG. 1, a preferred embodiment process in accordance with the invention involves transferring or depositing, such as by printing, one or more materials or material layers carried on the print ribbon 120 onto the substrate 10. Generally, this is accomplished by positioning the substrate 10 to a desired position or location relative to the print ribbon 120, denoted as operation A in FIG. 1. Depending upon the particular printing system 100 being used, this operation may be partially or entirely performed by placing the substrate at a sufficient proximity to the ribbon 120 such that upon operation of the system 100, the ribbon 120 can be contacted with the substrate 10. It will be understood that the invention includes operations in which the substrate 10 remains stationary and the ribbon 120 is exclusively moved.

The preferred process also comprises an operation in which the print ribbon 120 or a portion thereof, is displaced to thereby achieve contact between the outer face 132 of the adhesive layer 130 and the receiving face 12 of the base layer 14 of the substrate 10. This operation is denoted in FIG. 1 as operation B.

As will be appreciated, at the time at which contact occurs between faces 132 of the print ribbon 120 and the receiving face 12 of the substrate 10, the temperature of the release layer 150 and preferably also the adhesive layer 130 is at least equal to or greater than the glass transition temperature of the layer 130. That is, although it is not necessary that the adhesive layer 130 be heated to its glass transition temperature, it is generally preferred. This promotes adherence of the adhesive material in layer 130 onto the receiving face 12 of the substrate 10. As transfer of layer 130 from the print ribbon 120 to the substrate 10 occurs, the electrically conductive layer 140 and preferably the thermoplastic release layer 150 are also transferred to the substrate 10 to thereby form a preferred embodiment trace 200 as illustrated in FIG. 1. This operation is denoted as operation C in FIG. 1.

The present invention includes a range of preferred embodiment traces and circuits. For example, multiple sets of layers can be deposited partially or entirely upon one another to form conductive traces or circuits having increased thicknesses. Providing and forming traces and circuits having increased thicknesses serve to increase the cross sectional area of the resulting trace or circuit, thereby enabling an artisan to selectively adjust the electrical resistance of the trace or circuit of interest. Without being limited to any particular physical properties or characteristics, the bulk electrical conductivity of the preferred electrically conductive layer 140 is approximately 5.4 micro-ohm cm. Accordingly, the physical dimensions and relative proportions of circuit traces, i.e. the trace width, length, and thickness, are adjusted to provide the desired electrical resistance for the heating circuit of interest. Metallograph ribbons are known which are capable of depositing or otherwise forming traces in a range of thicknesses such as for example, from about 50 angstroms (0.005 microns) to about 4500 angstroms (0.45 microns) in a single pass. Metallograph ribbons are available from IIMAK of Amherst, N.Y. It is also contemplated that printers with registration and/or multiple printing heads can be utilized for forming multiple layers.

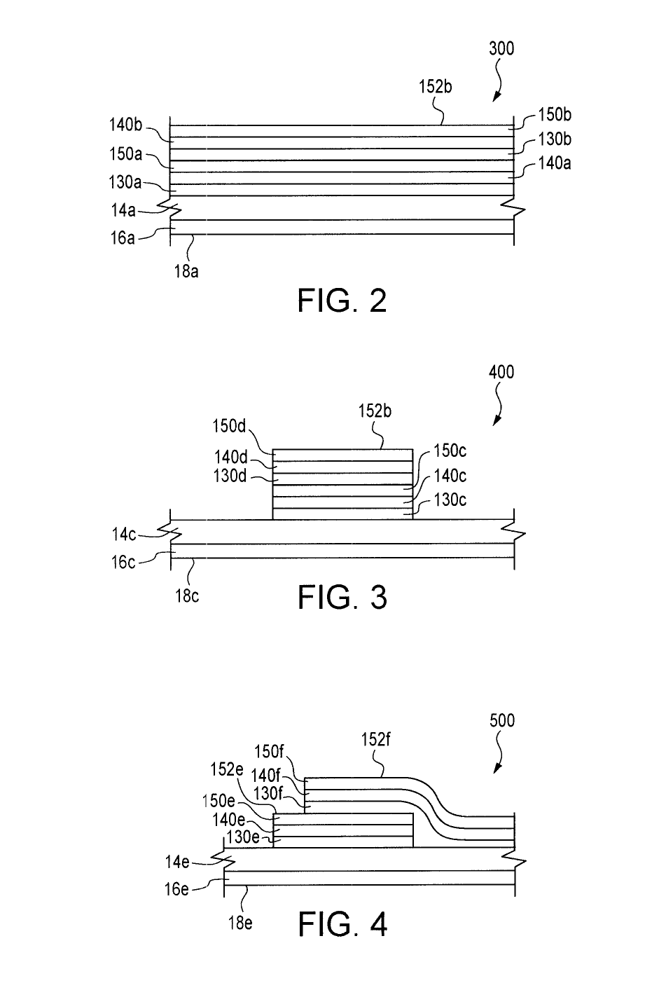

FIG. 2 schematically illustrates a cross section of another preferred embodiment trace 300 in accordance with the present invention. In the following description, it will be understood that reference numerals similar to those used in FIG. 1, refer to like materials and features. Thus for example, the description for layer 14a in FIG. 2 corresponds to the description for layer 14 provided in association with FIG. 1. The trace 300 comprises a substrate base layer 14a having an underside along which an optional pressure sensitive layer 16a can be provided. The layer 16a defines an exposed face 18a. The trace 300 also comprises a first set of layers including an adhesive layer 130a, an electrically conductive layer 140a, and a release layer 150a; and a second set of layers including an adhesive layer 130b, an electrically conductive layer 140b, and a release layer 150b.

FIGS. 3 and 4 illustrate additional preferred embodiment traces 400 and 500. The trace 400 depicted in FIG. 3 includes two or more sets of layers 130, 140, 150 which are identically aligned and positioned relative to one another. Thus, the first set of layers 130c, 140c, and 150c disposed on layers 14c and 16c are entirely covered by the second set of layers 130d, 140d, and 150d. The invention also includes traces having arrangements of layers in which one set of layers only partially covers an underlying set of layers. An example of this layer configuration is depicted in FIG. 4. A preferred trace 500 comprises a substrate base layer 14e and optional pressure sensitive adhesive layer 16e disposed along an underside, and having a first set of layers 130e, 140e, and 150e disposed on an oppositely directed receiving face of the substrate base layer. A second set of layers 130f, 140f, and 150f are partially disposed on the first set of layers and also on the substrate base layer 14e. A portion of the face 152e is exposed as shown in FIG. 4. In all of the embodiments comprising multiple sets of layers 130, 140, and 150, it is contemplated that the printing system 100 can be utilized to deposit one or more of the layer sets upon a previously deposited set of layers.

The present invention provides electrical traces having a wide range of widths. For example, typical trace widths are from about 0.015 inches (about 380 microns) to about 0.100 inches (about 2540 microns). However, it will be appreciated that narrower and wider trace dimensions can be utilized.

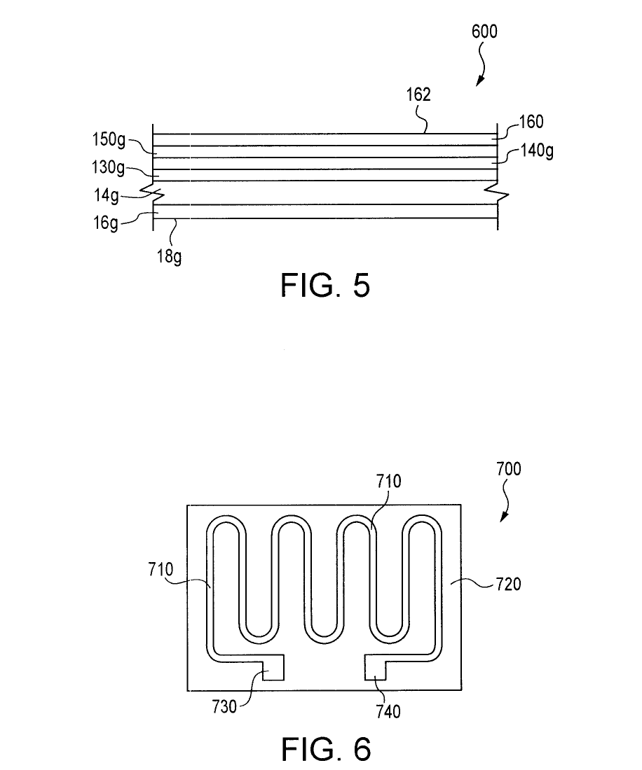

The present invention also includes the use of one or more additional layers in combination with the previously described thermoplastic adhesive layer 130, the electrically conductive layer 140, and the thermoplastic release layer 150. FIG. 5 is a schematic cross sectional view of another preferred embodiment trace 600. The trace 600 comprises a substrate base layer 14g having an optional adhesive layer 16g along its underside, and a set of the previously described layers 130g, 140g, and 150g. The trace 600 also comprises a layer 160 of a dielectric material preferably disposed on the previously noted first set of layers. The dielectric layer 160 defines an outer face 162. It is also contemplated that the one or more additional layers, e.g. the dielectric layer, could be deposited by the printing system 100 or by any other suitable system. Dielectric materials are well known in the art. Examples of a dielectric material include an acrylic material or a polyester material. In some high voltage applications (e.g., over 100 Volts), a 1 Mil polyester file applied with a pressure sensitive adhesive may be preferred. Various dielectric materials suitable for the preferred embodiments are available from IIMAK of Amherst, N.Y. For a dielectric layer, such as layer 160 depicted in FIG. 5, it will be appreciated that a wide range of thicknesses may be used depending upon the materials and the end use application of the trace. Generally, thicknesses for the dielectric layer range from about 0.5 micron to about 2.5 micron, and preferably from about 1.3 micron to about 1.5 micron.

The preferred embodiment electrically resistive traces are disposed upon a wide array of substrates. Typically, the substrates form or are a component of an electrical heater device described in greater detail. Preferably, the substrates are adapted for thermal transfer of heat generated from the electrically resistive trace or circuit. FIG. 8 is a cross sectional schematic view of a preferred embodiment thermal transfer substrate 800 used in the assemblies described herein. The thermal transfer substrate 800 comprises a substrate layer 820 which as noted is typically heat stabilized polyester or polyimide having a thickness of from about 25 to about 50 microns. The substrate layer 820 defines a first face 822 on which the resistive trace(s) are disposed, and an oppositely directed second face 824. The substrate 800 also comprises an optional pressure sensitive adhesive layer 830 disposed along the second face 824 of the substrate layer 820. A typical thickness of the adhesive layer 830 is about 25 microns. The substrate 800 may also comprise an optional release liner 840 extending along an otherwise exposed face of the adhesive layer 830. The substrate 800 preferably includes a topcoat layer 810 disposed on the first face 822 of the substrate layer 820. The topcoat layer 810 or ink receptive layer promotes bonding of a trace assembly and in particular a thermoplastic polymer layer of the trace assembly (not shown) to the substrate 800. A typical thickness of the topcoat layer 810 is from about 4 to about 8 microns.

FIG. 9 is a cross sectional schematic view of another preferred embodiment thermal transfer substrate 900 in accordance with the present invention. The substrate 900 serves to receive a trace assembly disposed thereon. The substrate 900 comprises a substrate layer 910 which as noted is typically formed from heat stabilized polyester or corona treated polyimide having a thickness of from about 25 to about 50 microns. The substrate layer 910 defines a first face 922 and an oppositely directed second face 924. The substrate 900 may optionally also include a layer 920 of a pressure sensitive adhesive and a release liner 930 as shown in FIG. 9.

The substrates for depositing or otherwise forming the electrically resistive traces upon, can in certain applications, be obtained from one or more commercial suppliers. For example, a suitable thermal transfer substrate can be obtained from Flexcon under the designation 21940 or from Polyonics under the designation XF-603. Typically, these substrates include an ink receptive topcoat. Preferably, rather than using special purpose materials specifically designed for thermal transfer printing, certain heat stabilized polymeric films are utilized. Examples of heat stabilized polymeric films include, but are not limited to, heat stabilized polyester films available under the designation MELINEX® ST™ from Dupont Teijin Films through Tekra Corporation of New Berlin, Wis. Unlike unstabilized PET films which experience distortion and shrinkage in high temperature applications and skewing during processing, MELINEX® ST™ stabilized films provide predictable dimensional stability, lower and more uniform shrinkage, and flatter surfaces. These films are available in thicknesses as low as 2 mils (50 microns). Specifically, MELINEX® ST™ films provide predictable dimensional changes with variable heat and moisture, superior sheet flatness for better web handling and higher yields, high tensile strength and stiffness to permit higher processing speeds, resistance to moisture and chemicals in demanding applications, and engineered surfaces with primer systems to resolve difficult adhesion challenges. These films are subjected to thermal stabilization which enables higher temperature film processing and versatility in a wide range of processes and applications. These films widen the working temperature of PET films from approximately 185° F. (85° C.) to 302° F. (150° C.) or higher. A most preferred film for the substrate in the preferred embodiments described herein is a heat stabilized polyester film designated as MELINEX° ST505.

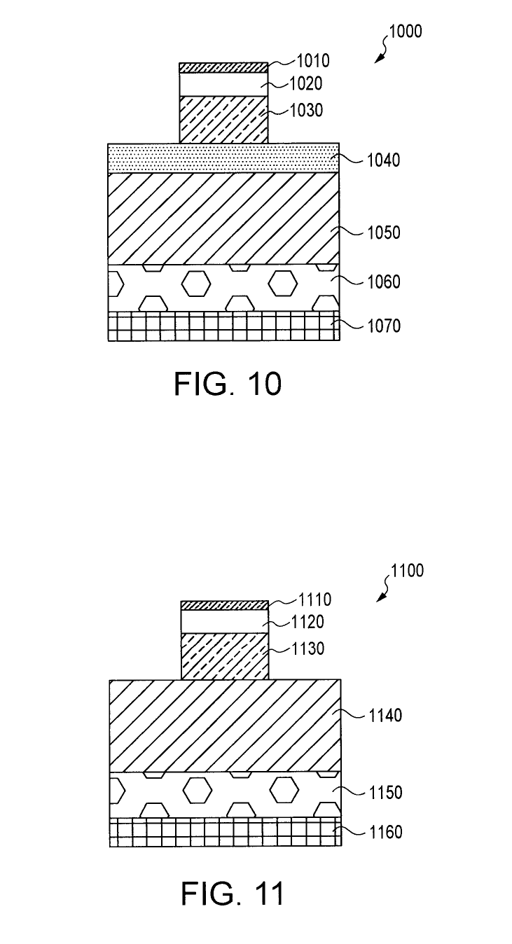

FIG. 10 is a cross sectional schematic view of another preferred embodiment trace disposed on a preferred embodiment substrate in accordance with the invention. The collective assembly is referred to as a formed trace 1000. The formed trace 1000 comprises a plurality of layers 1010, 1020, and 1030 disposed on a substrate assembly including layers 1040, 1050, 1060, and 1070. The layers 1040, 1050, 1060, and 1070 correspond to layers 810, 820, 830, and 840 respectively, previously described in conjunction with FIG. 8. The layers 1010, 1020, and 1030 are preferably transferred onto the substrate assembly by a thermal printer and thermal print ribbon as described herein. The layer 1010 is a thermoplastic release layer having a thickness of less than 0.1 microns. The layer 1020 is a conductive material layer such as aluminum having a thickness of about 0.26 microns. And, the layer 1030 is a thermoplastic adhesive layer having a thickness of about 0.5 microns. Layer 1030 is bonded to the layer 1040 such as after printing.

FIG. 11 is a cross sectional schematic view of another preferred embodiment trace disposed on a preferred embodiment substrate in accordance with the present invention. The collective assembly is referred to as a formed trace 1100. The formed trace 1100 comprises a plurality of layers 1110, 1120, and 1130 disposed on a substrate assembly including layers 1140, 1150, and 1160. The layers 1140, 1150, and 1160 correspond to layers 910, 920, and 930, respectively, previously described in conjunction with FIG. 9. The layers 1110, 1120, and 1130 are preferably transferred onto the substrate assembly by a thermal printer and thermal print ribbon as described herein. The layer 1110 is a thermoplastic release layer having a thickness of less than 0.01 micron. The layer 1120 is a conductive material such as aluminum having a thickness of about 0.26 microns. The layer 1130 is a thermoplastic adhesive layer bonded to layer 1140 after printing. The thickness of the layer 1130 is about 0.5 microns.

FIG. 13 is a cross sectional schematic view of a preferred embodiment encapsulated trace disposed on a substrate, collectively designated as assembly 1200. The assembly 1200 comprises an outer thermoplastic release layer 1210, typically having a thickness of less than 0.1 micron. The assembly 1200 also comprises a layer 1220 of a dielectric material such as an acrylic having a thickness of from about 1.3 to about 1.5 microns. The layer 1230 is a layer of a thermoplastic bonding layer having a thickness of about 0.5 microns. The layer 1240 is a thermoplastic release layer 1240 having a thickness of less than 0.1 micron. The layer 1250 is a conductive material such as aluminum having a thickness of about 0.26 micron. The layer 1260 is a thermoplastic adhesive layer having a thickness of about 0.5 micron. The layers 1210, 1220, 1230, 1240, 1250, and 1260, are preferably all deposited onto the substrate assembly of layers 1270, 1280, and 1290 by a thermal printer and thermal print ribbon as described herein. The substrate assembly layers 1270, 1280, and 1290 correspond to layers 820, 830, and 840, respectively of FIG. 8, or layers 910, 920, and 930, respectively of FIG. 9.

The present invention includes incorporating one or more additional layers such as the previously noted dielectric layer or topcoat layer in one or more, or all of the multiple sets of layers used in the resistive traces, illustrated for example in FIGS. 2-5, 10, 11, and 13.

Electrical contact to and/or from the traces and circuits described herein can be achieved in a variety of different ways. Examples of provisions for establishing electrical contact include but are not limited to, insulation displacement connectors (IDC), zero insertion force connectors (ZIF), surface mounting components using electrically conductive adhesives, directly adhering wires using conductive adhesives and the like.

A significant feature of the present invention is that the electrically conductive traces and/or circuits can be used immediately after their formation. That is, the traces or circuits upon deposition onto a suitable base or substrate, do not require any drying, curing, or other operation. This represents a significant advance in the art.

### Thermal Transfer Printers

An array of thermal transfer deposition and printing techniques can be used to form the preferred embodiment electrically conductive traces and circuits described herein. Generally, a thermal transfer printer is used to deposit an electrically conductive layer and associated layers as described herein onto a receiving face of a substrate.

Generally, such printers use a fixed width thermal printhead, pressing onto a paper or plastic label, over a driven rubber roller or platen. Between the printhead and the label is sandwiched a very thin thermal transfer ribbon (or sometimes referred to as “foil”), which conventionally includes a polyester film which has been coated on the label side with a wax, wax-resin or pure resin “ink”. The ribbon typically is spooled onto reels and is driven through the printing mechanism in sync with the labels, at speeds of up to 12 inches per second, although 6 inches per second is adequate for most applications. For the various preferred embodiments, ribbon speeds are approximately 2 inches per second.

As the label and ribbon are driven beneath the printhead together, small pixels across the width of the printhead are heated and cooled so as to melt the “ink” off the polyester film and onto the label. This process occurs very quickly and accounts for the fast speed of the printers and is dry instantly or nearly so. Thermal printheads are often 203 dots per inch (8 dots per mm) or 300 dpi (12 dots per mm), and up to 600 dpi or more. For example, thermal printheads have been developed that print at up to 2400 dpi.

Because of demands for relatively high print speeds, thermal transfer printers have become very sophisticated, with powerful processors and large memory capacities, to allow them to produce the desired images or patterns to be printed at the same speed as the print mechanism. To achieve this speed, almost all thermal printers use special internal description languages to allow the desired image or pattern to be laid out, i.e. configured, in the printers' memory prior to printing. Each manufacturer has their own software language and some are very complex.

Although numerous thermal transfer printers are commercially available, a preferred printer is a multi-head thermal transfer printer available from Matan Printers of Williamsville, N.Y. A multi-head thermal transfer printer could be used to continuously, i.e. roll to roll, print multiple layer circuits such as for example, having two or more layers of electrically conductive material and two layers of dielectric material, at a rate of approximately 2 linear inches per second.

### Thermal Transfer Ribbon

In addition to the preferred thermal transfer ribbons described herein, other versions and compositions can be used such as those disclosed in WO 2009/025762.

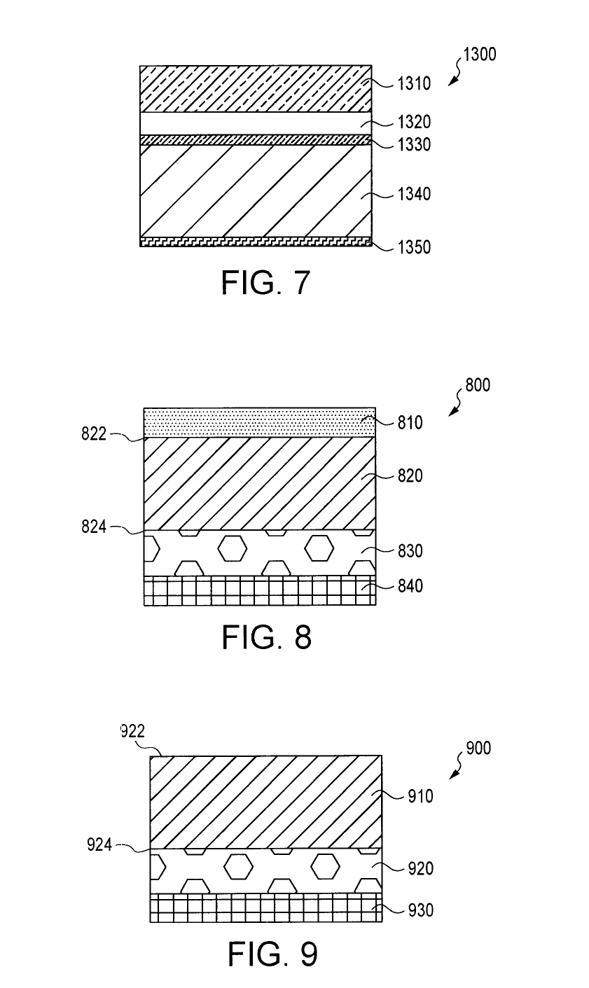

FIG. 7 is a cross sectional schematic view of a preferred embodiment thermal transfer ribbon 1300, depicted prior to a printing operation and transfer of layers onto a receiving substrate. The preferred ribbon 1300 comprises a thermoplastic adhesive layer 1310 that upon printing, bonds to a receiving substrate. The adhesive layer 1310 is typically about 0.5 micron thick. The ribbon 1300 also comprises a conductive material 1320 which is typically aluminum having a thickness of about 0.26 micron. The ribbon 1300 also comprises a thermoplastic release layer 1330 that enables the conductive layer 1320 to be removed from a carrier layer 1340 during printing. A typical thickness for the release layer 1330 is less than 0.1 micron. The ribbon 1300 also comprises a polyester carrier film 1340 for the layers 1310, 1320, and 1330. The carrier film 1340 has a typical thickness of about 4.5 microns. The ribbon 1300 may further comprise a lubrication layer 1350 which can for example be a cross-linked silicone material which serves as a lubricating layer between the ribbon and the printer head.

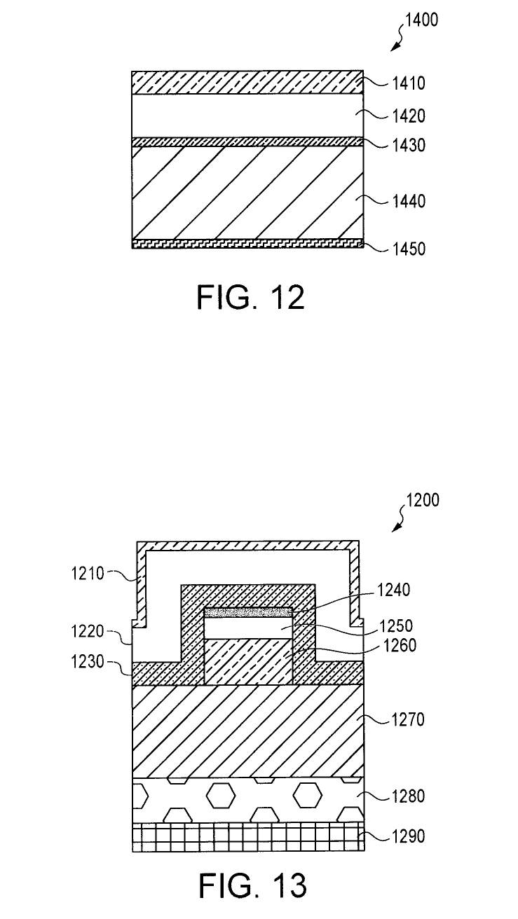

FIG. 12 is a cross sectional schematic view of another preferred embodiment ribbon 1400. The ribbon 1400 comprises a thermoplastic adhesive layer 1410 that bonds to a previously deposited or formed trace or circuit on a substrate. Layer 1410 has a thickness of about 0.5 micron. The ribbon 1400 also comprises a dielectric layer 1420 that can for example be a dielectric material such as acrylic having a thickness of from about 1.3 to about 1.5 microns. The ribbon 1400 also comprises a thermoplastic release layer 1430 that allows deposition of the dielectric layer 1440 during printing. The release layer 1430 has a typical thickness of less than 0.1 micron. The ribbon 1400 also comprises the polyester carrier film 1440 having a typical thickness of about 4.5 microns. And, the ribbon 1400 comprises a lubrication layer 1450 which is typically a layer of cross-linked silicone that serves as a lubrication layer between the ribbon and printhead.

Thus, it will be appreciated that the various preferred ribbons may include conductive materials for forming the resistive traces. The preferred ribbons can also include dielectric materials for forming protective or encapsulating layers onto traces or circuits.

### Heating Element and Device

The heating element can be in nearly any size, shape, and/or configuration. Preferably, the trace or traces that are formed exhibit a bulk electrical resistivity of from about 2.4 micro-ohm-centimeters to about 10 micro-ohm-centimeters, with about 5.4 micro-ohm centimeters being preferred. Generally, it is preferred that the bulk electrical resistivity of the traces is equal or substantially so to that of the bulk material.

FIG. 6 illustrates a preferred embodiment heater 700 formed in accordance with the present invention. The heater 700 comprises one or more traces collectively referred to herein as traces 710 disposed on a substrate 720. The traces 710 may be in nearly any form and may include a single continuous trace extending between a first contact pad 730 and a second contact pad 740. The contact pads are electrically conductive and are in electrical communication with the traces 710. Alternatively, the traces may be in the form of collections of individual traces, series or parallel circuits to obtain desired resistance.

The heater 700 may also optionally include one or more layers of an adhesive generally disposed on the traces 710. It will be appreciated that the layer of adhesive is typically applied onto the traces and substrate after deposition, i.e. printing, of the traces. Use of such adhesive layer enables adhesive attachment of the heater to a device, substrate, or component.

The heater 700 may also optionally include one or more encapsulating material layers or topcoat layers. Typically, the encapsulating layer is formed from the same material as used for the substrate 720. This practice ensures similar or identical thermal expansion characteristics and other physical properties over the entire heater 700. Use of an encapsulating material may provide protection for the heater such as against external factors and moisture.

The resulting heater 700 can be formed in nearly any size, shape and/or configuration.

Many other benefits will no doubt become apparent from future application and development of this technology.

All patents, published applications, and articles noted herein are hereby incorporated by reference in their entirety.

It will be understood that any one or more feature or component of one embodiment described herein can be combined with one or more other features or components of another embodiment. Thus, the present invention includes any and all combinations of components or features of the embodiments described herein.

As described hereinabove, the present invention solves many problems associated with previous type devices. However, it will be appreciated that various changes in the details, materials and arrangements of parts, which have been herein described and illustrated in order to explain the nature of the invention, may be made by those skilled in the art without departing from the principle and scope of the invention, as expressed in the appended claims.

1. An electrically conductive trace comprising:
a polymeric substrate defining an underside face and an oppositely directed receiving face;
a thermoplastic adhesive layer disposed on the receiving face of the polymeric substrate;
an electrically conductive layer disposed on the thermoplastic adhesive layer; and
a thermoplastic release layer disposed on the electrically conductive layer.

2. The trace of claim 1 wherein the thermoplastic adhesive layer exhibits a glass transition temperature of from about 80° C. to about 90° C.

3. The trace of claim 2 wherein the thermoplastic adhesive layer exhibits a glass transition temperature of about 85° C.

4. The trace of claim 1 wherein the thermoplastic adhesive layer has a thickness of from about 0.1 micron to about 1 micron.

5. The trace of claim 4 wherein the thermoplastic adhesive layer has a thickness of about 0.5 microns.

6. The trace of claim 1 wherein the electrically conductive layer includes at least one agent selected from the group consisting of aluminum, silver, gold, and combinations thereof.

7. The trace of claim 1 wherein the electrically conductive layer has a thickness of from about 50 angstroms to about 4500 angstroms.

8. The trace of claim 7 wherein the electrically conductive layer has a thickness of about 2500 angstroms.

9. The trace of claim 1 wherein the thermoplastic release layer exhibits a glass transition temperature of from about 80° C. to about 90° C.

10. The trace of claim 9 wherein the thermoplastic release layer exhibits a glass transition temperature of about 85° C.

11. The trace of claim 1 wherein the thermoplastic release layer has a thickness less than about 1 micron.

12. The trace of claim 11 wherein the thermoplastic release layer has a thickness less than about 0.1 microns.

13. The trace of claim 1 further comprising:
an adhesive layer disposed on the underside of the polymeric substrate.

14. The trace of claim 13 wherein the adhesive layer disposed on the underside of the polymeric substrate is a pressure sensitive adhesive.

15. The trace of claim 1 further comprising:
a dielectric layer disposed on the thermoplastic release layer.

16. The trace of claim 15 wherein the dielectric layer includes a material selected from the group consisting of an acrylic material or a polyester material.

17. The trace of claim 1 wherein the thermoplastic adhesive layer is a first adhesive layer, the electrically conductive layer is a first electrically conductive layer, and the thermoplastic release layer is a first release layer, the trace further comprising:
a second thermoplastic adhesive layer disposed on the first release layer;
a second electrically conductive layer disposed on the second thermoplastic adhesive layer; and
a second thermoplastic release layer disposed on the second electrically conductive layer.

18. The trace of claim 17 wherein the second thermoplastic adhesive layer exhibits a glass transition temperature of from about 80° C. to about 90° C.

19-30. (canceled)

31. A heating device having at least one electrically resistive heating circuit disposed on a substrate, the circuit including an electrically conductive trace, the trace comprising:
a thermoplastic adhesive layer disposed on the substrate;
an electrically conductive layer disposed on the thermoplastic adhesive layer; and
a thermoplastic release layer disposed on the electrically conductive layer.

32-39. (canceled)

40. A method of forming an electrically conductive trace on a substrate, the method comprising:
providing a substrate defining a receiving face;
providing a thermal transfer printer and a thermal transfer ribbon, the ribbon including (i) an outermost thermoplastic adhesive layer, (ii) an electrically conductive material, (iii) a thermoplastic release layer, and (iv) a carrier film, the printer including provisions for selectively moving and advancing the ribbon;
printing (i) the thermoplastic adhesive layer, (ii) the electrically conductive material, and (iii) the thermoplastic adhesive layer on the receiving face of the substrate to form the trace.

41-44. (canceled)
